(19) United States
(12) Patent Application Publication
(10) Pub. No.: US 2017/0001223 A1
(43) Pub. Date: Jan. 5, 2017

(54) METHOD AND APPARATUS FOR TREATING SUBSTRATE

(71) Applicant: SEMES CO., LTD., Chungcheongnam-do (KR)

(72) Inventor: TAEKYOUB LEE, Chungcheongnam-do (KR)

(21) Appl. No.: 15/186,745

(22) Filed: Jun. 20, 2016

(30) Foreign Application Priority Data
Jun. 30, 2015 (KR) 10-2015-0093128

(51) Int. Cl. B08B 3/08; H01L 21/02; B08B 3/10

(52) U.S. Cl. CPC B08B 3/08; B08B 3/10; H01L 21/02052

(57) ABSTRACT

Disclosed is a method for treating a substrate, the method including a pre-wetting operation of discharging pure water onto an upper surface of the substrate, and a treatment operation of treating the substrate by supplying a treatment liquid onto the upper substrate, after the pre-wetting operation, wherein the method further includes a static electricity removing operation of removing static electricity by discharging a static electricity removing liquid onto a lower surface of the substrate, before the treatment operation.

### CROSS-REFERENCE TO RELATED APPLICATIONS

A claim for priority under 35 U.S.C. §119 is made to Korean Patent Application No. 10-2015-0093128 filed Jun. 30, 2015, in the Korean Intellectual Property Office, the entire contents of which is hereby incorporated by reference.

### BACKGROUND

The inventive concept relates to an apparatus and a method for treating a substrate, and more particularly to an apparatus and a method for treating a substrate, which removes static electricity generated on a surface of the substrate.

Contaminants such as particles, organic contaminants, and metallic contaminants on a surface of a substrate greatly influence the characteristics and yield rate of a semiconductor device. Due to this, a cleaning process of removing various contaminants attached to a surface of a substrate is very important, and a process of cleaning a substrate is performed before and after unit processes for manufacturing a semiconductor.

In general, a process of cleaning a substrate includes a treatment process of removing metallic substances, organic substances, and particles residing on a substrate by using a treatment liquid such as a chemical, a rinsing process of removing the treatment liquid residing on the substrate by using pure water, and a drying process of drying the substrate by using a drying gas.

Meanwhile, a pre-wetting process of injecting pure water onto a pattern surface of a substrate to easily diffuse a chemical, which is to be applied before the treatment process and reduce particles generated when the treatment liquid makes direct contact with the dried substrate.

However, as in FIG. 1, static electricity is generated due to friction between the pattern surface and pure water during a pre-wetting process. If the treatment liquid is injected onto the pattern surface in this state, electric charges accumulated on the surface of the substrate is discharged to a part, with which the treatment liquid is in contact, causing an arcing phenomenon, and accordingly, the pattern of the substrate is damaged as in FIG. 2.

### SUMMARY

The inventive concept provides an apparatus and a method for treating a substrate, which removes static electricity generated on a surface of a substrate.

The inventive concept also provides an apparatus and a method for treating a substrate, which prevents an arcing phenomenon generated on a surface of the substrate and damage to a pattern of the substrate.

The aspect of the inventive concept is not limited thereto, and other unmentioned aspects of the inventive concept may be clearly appreciated by those skilled in the art from the following descriptions.

The inventive concept provides a method for treating a substrate.

In accordance with an aspect of the inventive concept, there is provided a method for treating a substrate, the method including a pre-wetting operation of discharging pure water onto an upper surface of the substrate, and a treatment operation of treating the substrate by supplying a treatment liquid onto the upper substrate, after the pre-wetting operation, wherein the method further includes a static electricity removing operation of removing static electricity by discharging a static electricity removing liquid onto a lower surface of the substrate, before the treatment operation.

According to an embodiment, the static electricity removing operation may be performed after the pre-wetting operation.

According to an embodiment, the static electricity removing operation and the pre-wetting operation may be performed at the same time.

According to an embodiment, the treatment liquid may be a conductive liquid.

According to an embodiment, the treatment liquid may be a fluoride hydrogen (HF) solution or a solution including ammonium hydroxide (NH₄OH), hydrogen peroxide (H₂O₂), and water (H₂O).

According to an embodiment, the static electricity removing liquid may be a chemical.

According to an embodiment, the static electricity removing liquid may be a conductive liquid.

According to an embodiment, the static electricity removing liquid may be a fluoride hydrogen (HF) solution or a solution including ammonium hydroxide (NH₄OH), hydrogen peroxide (H₂O₂), and water (H₂O).

According to an embodiment, the treatment liquid may be a chemical.

According to an embodiment, the method may further include a drying operation of drying the substrate, after the treatment operation.

According to an embodiment, the static electricity may flow through an interior of the substrate from the upper surface of the substrate, and discharged to a lower side of the substrate along the static electricity removing liquid flowing on the lower surface of the substrate to be removed.

The inventive concept provides a apparatus for treating a substrate.

In accordance with an aspect of the inventive concept, there is provided an apparatus for treating a substrate, the apparatus including a support unit that supports the substrate, an injection unit having a pure water injection member that discharges pure water onto an upper surface of the substrate and a treatment liquid injection member that supplies a treatment liquid onto the upper surface of the substrate, a back nozzle unit that injects a static electricity removing liquid onto a lower surface of the substrate, and a controller that controls the injection unit and the back nozzle unit, wherein the controller controls the injection unit and the back nozzle unit such that the treatment liquid injection member supplies a treatment liquid onto the upper surface of the substrate after the pure water injection member discharges the pure water onto the upper surface of the substrate and the back nozzle unit discharges the static electricity removing liquid onto the lower surface of the substrate before the treatment liquid is supplied.

According to an embodiment, the controller may control the injection unit and the back nozzle unit such that the static electricity removing liquid and the pure water are discharged at the same time.

According to an embodiment, the controller may control the injection unit and the back nozzle unit such that the static electricity removing liquid is discharged after the pure water is discharged.

According to an embodiment, the treatment liquid may be a conductive liquid.

According to an embodiment, the treatment liquid may be a fluoride hydrogen (HF) solution or a solution including ammonium hydroxide (NH₄OH), hydrogen peroxide (H₂O₂), and water (H₂O).

According to an embodiment, the static electricity removing liquid may be a chemical.

According to an embodiment, the static electricity removing liquid may be a conductive liquid.

According to an embodiment, the static electricity removing liquid may be a fluoride hydrogen (HF) solution or a solution including ammonium hydroxide (NH₄OH), hydrogen peroxide (H₂O₂), and water (H₂O)

According to an embodiment, the treatment liquid may be a chemical.

According to an embodiment, the injection unit may further include a gas injecting member that supplies a drying gas onto the upper surface of the substrate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating an arcing phenomenon by static electricity in a pre-wetting operation according to the related art;

FIG. 2 is a view illustrating that a pattern of a substrate is damaged due to arcing in the pre-wetting operation according to the related art;

FIG. 3 is a plan view schematically illustrating a substrate treating system provided with a substrate treating apparatus according to an embodiment of the inventive concept;

FIG. 4 is a view illustrating an embodiment of a substrate treating apparatus of FIG. 3;

FIG. 5 is a view illustrating a back nozzle unit;

FIG. 6 is a view illustrating a pre-wetting operation of discharging pure water;

FIG. 7 is a view illustrating a static electricity removing operation of discharging a static electricity removing liquid;

FIG. 8 is a view illustrating a treatment operation of discharging a treatment liquid;

FIG. 9 is a view illustrating a drying operation of injecting a drying gas;

FIG. 10 is a flowchart illustrating a method of treating a substrate according to an embodiment of the inventive concept; and

FIGS. 11 to 14 are views sequentially illustrating a process of removing static electricity from a substrate in the static electricity removing operation of FIG. 7.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

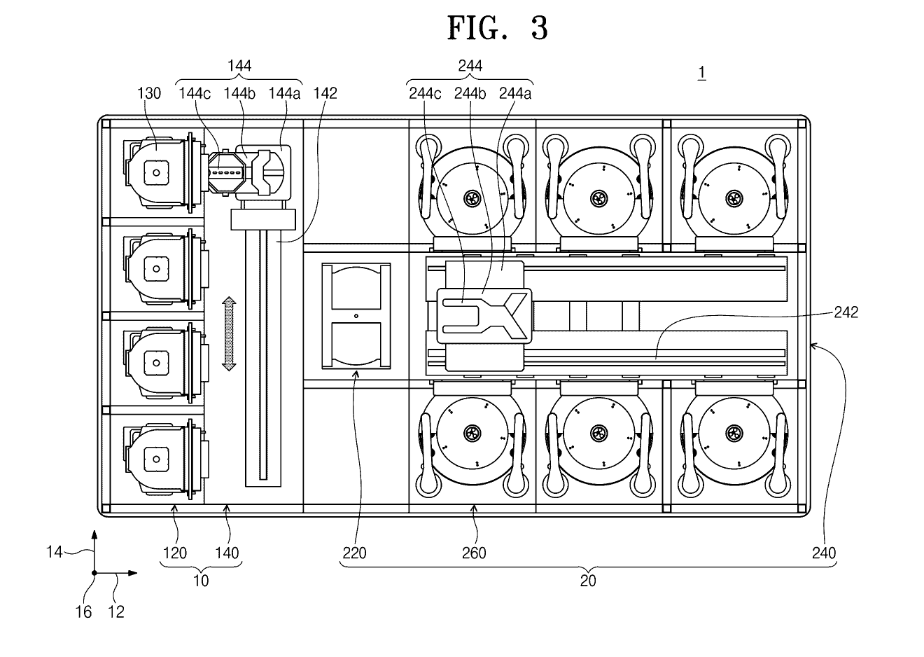

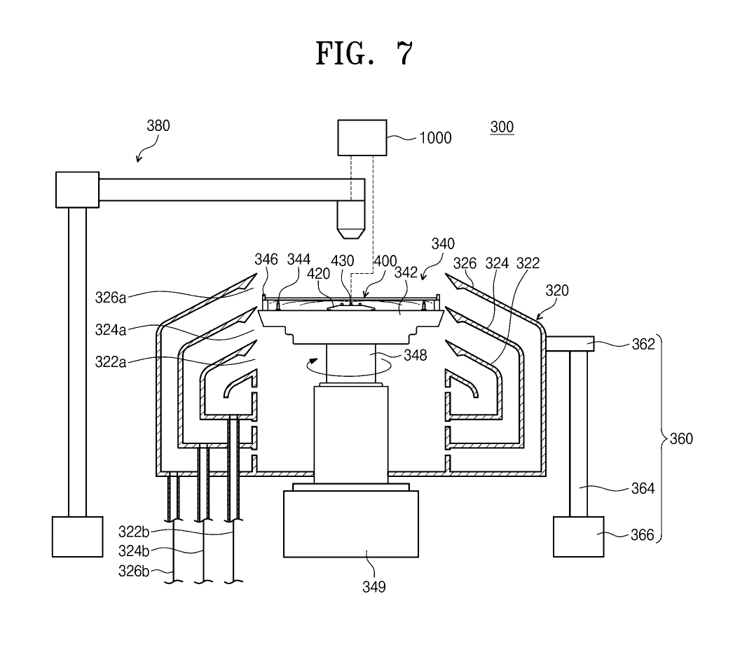

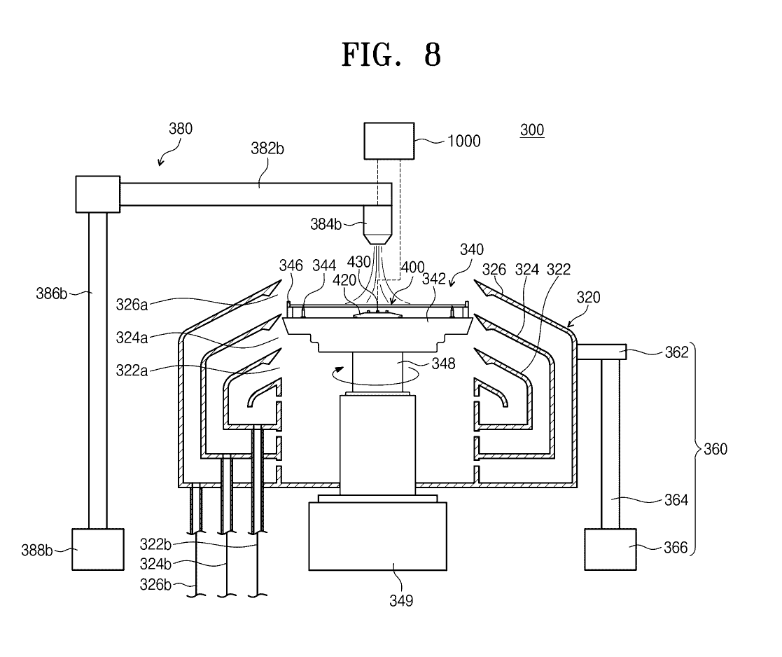

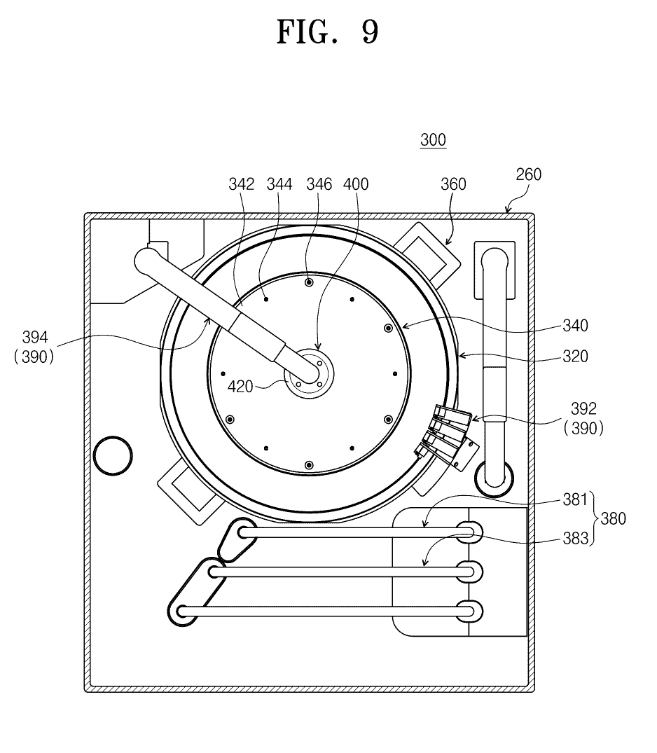

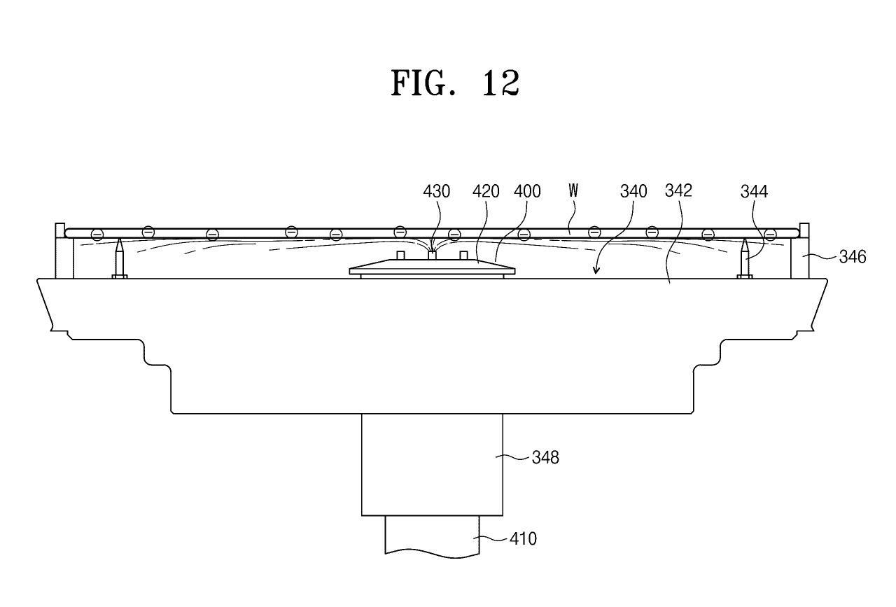

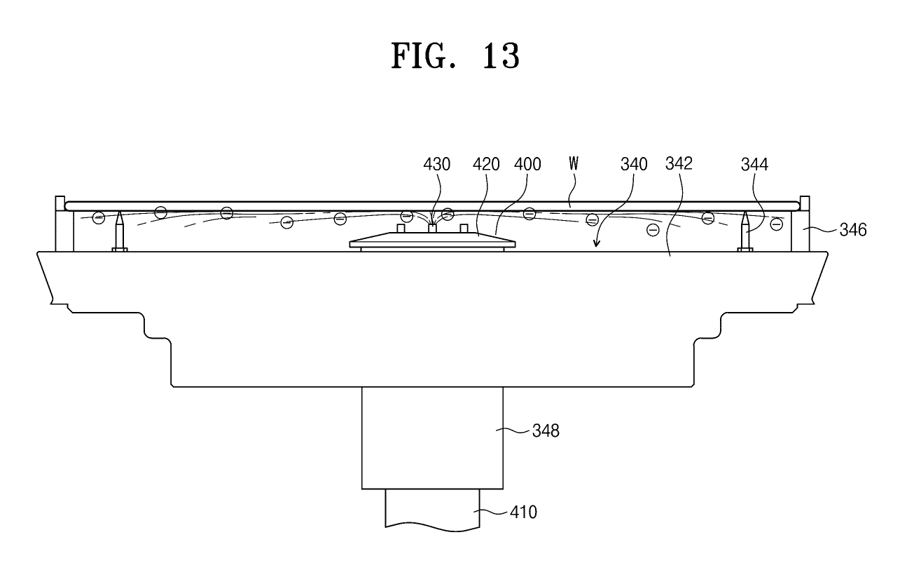

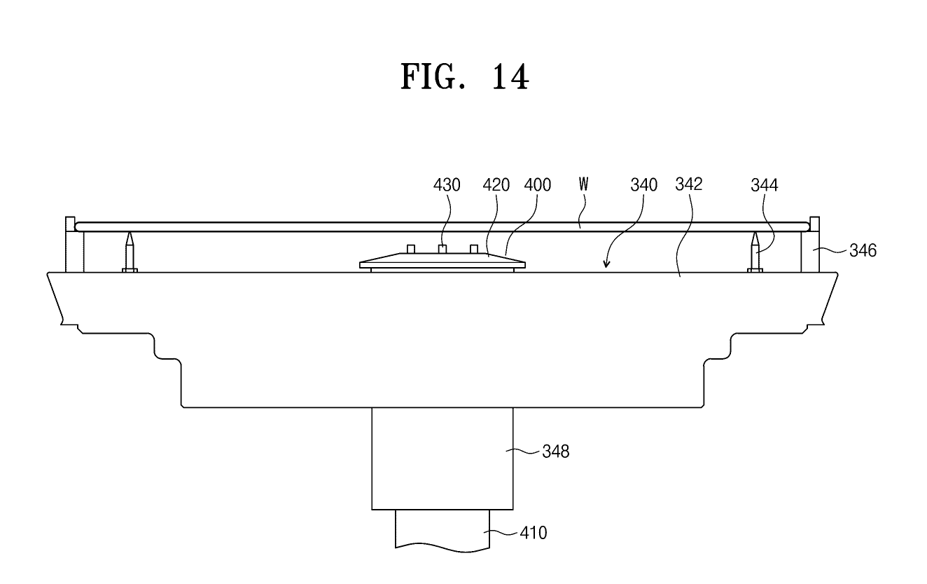

Hereinafter, exemplary embodiments of the inventive concept will be described with reference to FIGS. 3 to 14.

FIG. 3 is a plan view schematically illustrating a substrate treating system 1 according to the inventive concept.

Referring to FIG. 3, the substrate treating system 1 includes an index module 100 and a process treating module 200. The index module 100 includes a plurality of load ports 120 and a feeding frame 140. The load port 120, the feeding frame 140, and the process treating module 200 may be sequentially arranged in a row. Hereinafter, a direction in which the load port 120, the feeding frame 140, and the process treating module 200 are arranged will be referred to a first direction 12. A direction perpendicular to the first direction 12 when viewed from the top will be referred to as a second direction 14, and a direction normal to a plane including the first direction 12 and the second direction 14 will be referred to as a third direction 16.

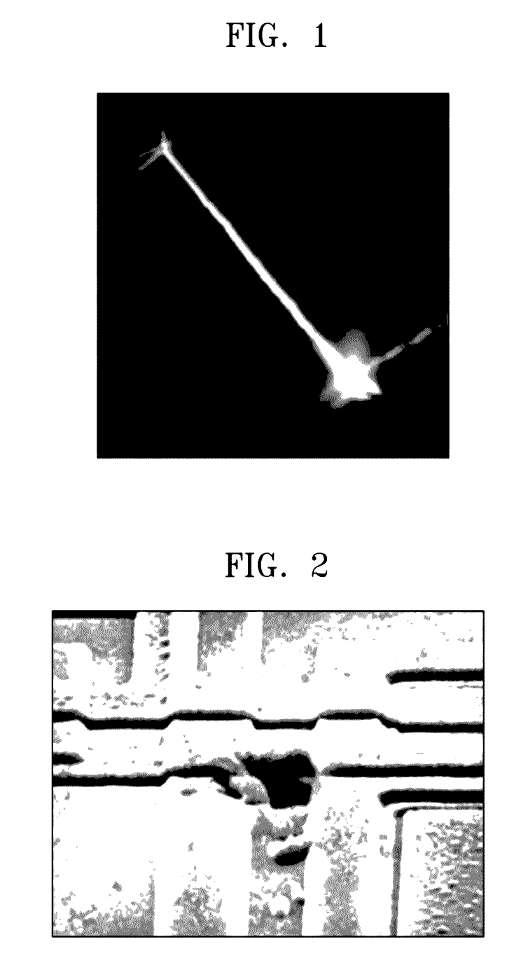

A carrier 130, in which a substrate W is received, is seated on the load port 120. A plurality of load ports 120 are provided, and are arranged along the second direction 14 in a row. FIG. 1 illustrates that four load ports 120 are provided. However, the number of the load ports 120 may increase or decrease according to a condition, such as the process efficiency of the process treating module 200 or a footprint. A plurality of slots (not illustrated) provided to support peripheries of substrates W are formed in the carrier 130. A plurality of slots are provided in the third direction 16. The substrates W are stacked in the carrier 130 while being spaced apart from each other along the third direction 16. A front opening unified pod (FOUP) may be used as the carrier 130.

The process treating module 200 includes a buffer unit 220, a feeding chamber 240, and a plurality of process chambers 260. The feeding chamber 240 is arranged such that the lengthwise direction thereof is in parallel to the first direction 12. The process chambers 260 are arranged on opposite sides of the feeding chamber 240 along the second direction 14. The process chambers 260 situated on one side of the feeding chamber 240 and the process chambers 260 situated on an opposite side of the feeding chamber 240 are symmetrical to each other with respect to the feeding chamber 240. Some of the process chambers 260 are arranged along the lengthwise direction of the feeding chamber 240. Furthermore, some of the process chambers 260 are arranged to be stacked on each other. That is, the process chambers 260 having an array of A by B (A and B are natural numbers) may be arranged on one side of the feeding chamber 240. Here, A is the number of the process chambers 260 provided in a row along the first direction 12, and B is the number of the process chambers 260 provided in a row along the third direction 16. When four or six process chambers 260 are provided on one side of the feeding chamber 240, the process chambers 260 may be arranged in an array of 2 by 2 or 3 by 2. The number of the process chambers 260 may increase or decrease. Unlike the above-mentioned description, the process chambers 260 may be provided only on one side of the feeding chamber 240. Further, unlike the above-mentioned description, the process chambers 260 may be provided on one side or opposite sides of the feeding chamber 240 to form a single layer.

A buffer unit 220 is arranged between the feeding frame 140 and the feeding chamber 240. The buffer unit 220 provides a space in which the substrates W stay before being transported between the feeding chamber 240 and the feeding frame 140. Slots (not illustrated) in which the substrates W is positioned are provided in the buffer unit 220, and a plurality of slots (not illustrated) are provided to be spaced apart from each other along the third direction 16. Faces of the buffer unit 220 that faces the feeding frame 140 and faces the feeding chamber 240 are opened.

The feeding frame 140 transports the substrates W between the carrier 130 seated on the load port 120 and the buffer unit 220. An index rail 142 and an index robot 144 are provided in the feeding frame 140. The index rail 142 is arranged such that the lengthwise direction thereof is in parallel to the second direction 14. The index robot 144 is installed on the index rail 142, and is linearly moved in the second direction 14 along the index rail 142. The index robot 144 has a base 144a, a body 144b, and a plurality of index arms 144c. The base 144a is installed to be moved along the index rail 142. The body 144b is coupled to the base 144a. The body 144b is provided to be moved along the third direction 16 on the base 144a. The body 144b is provided to be rotated on the base 144a. The index arms 144c are coupled to the body 144b, and are provided to be moved forwards and rearwards with respect to the body 144b. A plurality of index arms 144 are provided to be driven individually. The index arms 144 are arranged to be stacked so as to be spaced apart from each other along the third direction 16. Some of the index arms 144 are used when the substrates W are transported to the carrier 130 in the process module 200, and some of the index arms 144c may be used when the substrates W are transported from the carrier 130 to the process treating module 200. This structure may prevent particles generated from the substrates W before the process treatment from being attached to the substrates W after the process treatment in the process of carrying the substrates W in and out by the index robot 144.

The feeding chamber 240 transports the substrates W between the buffer unit 220 and the process chambers 260, and between the process chambers 260. A guide rail 242 and a main robot 244 are provided in the feeding chamber 240. The guide rail 242 is arranged such that the lengthwise direction thereof is in parallel to the first direction 12. The main robot 244 is installed on the guide rail 242, and is linearly moved along the first direction 12 on the guide rail 242. The main robot 244 has a base 244a, a body 244b, and a plurality of main arms 244c. The base 244a is installed to be moved along the guide rail 242. The body 144b is coupled to the base 244a. The body 244b is provided to be moved along the third direction 16 on the base 244a. The body 244b is provided to be rotated on the base 244a. The main arms 244c are coupled to the body 244b, and are provided to be moved forwards and rearwards with respect to the body 244b. A plurality of main arms 244c are provided to be driven individually. The main arms 244c are arranged to be stacked so as to be spaced apart from each other along the third direction 16. The main arms 244c used when the substrates W are transported from the buffer unit 220 to the process chambers 260 and the main arms 244c used when the substrates W are transported from the process chambers 260 to the buffer unit 220 may be different.

Substrate treating apparatuses 300 that perform cleaning processes on the substrates W are provided in the process chambers 260. The substrate treating apparatus 300 provided to the process chambers 260 may have different structures according to the types of the cleaning processes. Selectively, the substrate treating apparatuses 300 in the process chambers 260 may have the same structure. Selectively, the process chambers 260 may be classified into a plurality of groups such that the structures of the substrate treating apparatuses 300 in the process chambers 260 pertaining to the same group are the same and the structures of the substrate treating apparatuses 300 in the process chambers 260 pertaining to different groups are different. For example, when the process chambers 260 are classified into two groups, the first group of process chambers 260 may be provided on one side of the feeding chamber 240 and the second group of process chambers 260 may be provided on an opposite side of the feeding chamber 240. Selectively, the first group of process chambers 260 may be provided on the lower side of the feeding chamber 240 and the second group of process chambers 260 may be provided on the upper side of the feeding chamber 240, on opposite sides of the feeding chamber 240. The first group of process chambers 260 and the second group of process chambers 260 may be classified according to the kinds of the used chemicals or the types of cleaning methods.

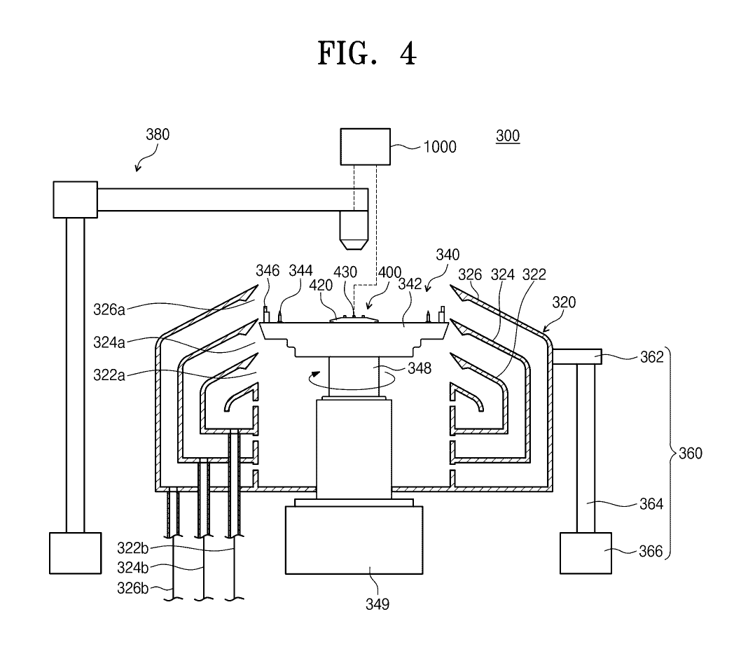

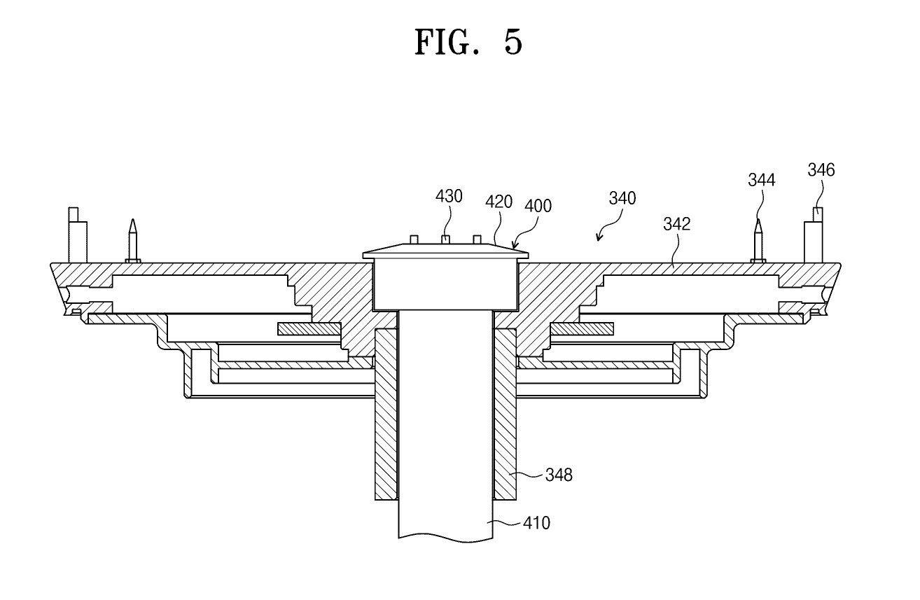

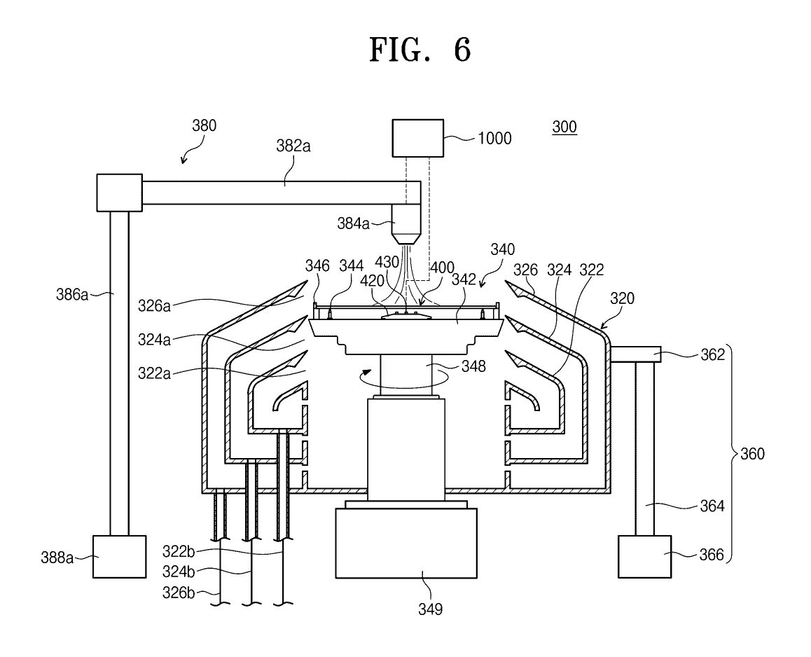

Hereinafter, an example of a substrate treating apparatus 300 that cleans a substrate W by using a treatment fluid will be described. FIG. 4 is a schematic view illustrating an example of the substrate treating apparatus 300. FIG. 5 is a view illustrating a back nozzle unit; FIGS. 6 to 9 are views sequentially illustrating a process of treating a substrate.

Referring to FIG. 4, the substrate treating apparatus 300 includes a cup 320, a support unit 340, an elevation unit 360, an injection unit 380, a gas injection member 390, a back nozzle unit 400, and a controller 1000. The cup 320 has a space for performing a substrate treating process, and an upper side of the cup 320 is opened. The cup 320 has an inner recovery vessel 322, an intermediate recovery vessel 324, and an outer recovery vessel 326. The recovery vessels 322, 324, and 326 recover different treatment fluids used in the process. The inner recovery vessel 322 has an annular ring shape that surrounds the support unit 340, the intermediate recovery vessel 324 has an annular ring shape that surrounds the inner recovery vessel 322, and the outer recovery vessel 326 has an annular ring shape that surrounds the intermediate recovery vessel 324. An inner space 322a of the inner recovery vessel 322, a space 324a between the inner recovery vessel 322 and the intermediate recovery vessel 324, and a space 326a between the intermediate recovery vessel 324 and the outer recovery vessel 326 function as inlets through which the treatment fluids are introduced into the inner recovery vessel 322, the intermediate recovery vessel 324, and the outer recovery vessel 326. Recovery lines 322b, 324b, and 326b extending from the recovery vessels 322, 324, and 326 perpendicularly in the downward direction of the bottom surfaces thereof are connected to the recovery vessels 322, 324, and 326, respectively. The recovery lines 322b, 324b, and 326b discharge the treatment fluids introduced through the recovery vessels 322, 324, 326, respectively. The discharged treatment fluids may be reused through an external treatment fluid recycling system (not illustrated).

The support unit 340 is arranged in a treatment space of the cup 320. The support unit 340 supports and rotates the substrate during the process. The support unit 340 has a body 342, a plurality of support pins 344, a plurality of chuck pins 346, and a drive shaft 348. The body 342 has an upper surface having a substantially circular shape when viewed from the top. The body 342 has a hollow portion at the center thereof. The drive shaft 348 that may be rotated by a driver 349 is fixedly coupled to the bottom of the body 342. The body 342 includes a support pin 344 and a chuck pin 346 to support the substrate. A plurality of support pins 344 are provided. The support pins 344 may be arranged to be spaced apart from each other at a periphery of the upper surface of the body 342 and protrude upwards from the body 342. The support pins 344 are arranged to have a generally annular ring shape through combination thereof. The support pins 344 support a periphery of a rear surface of the substrate such that the substrate W is spaced apart from the upper surface of the body 342 by a predetermined distance. A plurality of chuck pins 346 are provided. The chuck pins 346 are arranged to be more distant from the center of the body 342 than the support pins 344. The chuck pins 346 are provided to protrude upwards from the body 342. The chuck pins 346 support a side of the substrate such that the substrate is not separated laterally from a proper place when the support unit 340 is rotated. The chuck pins 346 are provided to be linearly moved between a standby position and a support position along a radial direction of the body 342. The standby position is a position that is more distant from the center of the body 342 than the support position. When the substrate is loaded on or unloaded from the support unit 340, the chuck pins 346 are located at the standby position, and when a process is performed on the substrate, the chuck pins 346 are located at the support position. The chuck pins 346 are in contact with the side of the substrate at the support position.

The elevation unit 360 linearly moves the cup 320 upwards and downwards. When the cup 320 is moved upwards and downwards, a relative height of the cup 320 to the support unit 340 is changed. The elevation unit 360 has a bracket 362, a movable shaft 364, and a driver 366. The bracket 362 is fixedly installed on an outer wall of the cup 320, and the movable shaft 364 that is moved upwards and downwards by the driver 366 is fixedly coupled to the bracket 362. The cup 320 is lowered such that, when the substrate W is positioned on the support unit 340 or is lifted from the support unit 340, the support unit 340 protrudes to the upper side of the cup 320. When the process is performed, the height of the cup 320 is adjusted such that the treatment fluid is introduced into the preset recovery vessel 360 according to the kind of the treatment fluid supplied to the substrate W. For example, the substrate is located at a height corresponding to an interior space 322a of the inner recovery vessel 322 while the substrate is treated by a first treatment fluid. Further, the substrate may be located at a height corresponding to a space 324a between the inner recovery vessel 322 and the intermediate recovery vessel 324 and a space 326a between the intermediate recovery vessel 324 and the outer recovery vessel 326 while the substrate is treated by a second treatment fluid and a third treatment fluid, respectively. Unlike those described above, the elevation unit 360 may move the support unit 340, instead of the cup 320, upwards and downwards.

The injection unit 380 injects the treatment fluid onto the substrate W. The treatment fluid may be pure water, a treatment liquid, and a drying gas. The injection unit 380 injects the treatment fluid onto an upper surface of the substrate W. Hereinafter, the upper surface of the substrate refers to a pattern surface on which a pattern is formed. The injection unit 380 may be rotated. The injection unit 380 includes a pure water injecting member 381, a treatment fluid injecting member 383, and a gas injecting member 390.

The pure water injecting member 381 injects pure water to the upper surface of the substrate. The pure water injecting unit 381 has a nozzle support 382a, a nozzle 384a, a support 386a, and a driver 388a. The lengthwise direction of the support 386a is provided along the third direction 16, and the driver 388a is coupled to a lower end of the support 386a. The driver 388a rotates and elevates the support 386a. The nozzle support 382a is coupled to an end of the support 386a, which is opposite to an end of the support 386a coupled to the driver 388a, perpendicularly to the support 386a. The nozzle 384a is installed on a bottom surface of an end of the nozzle support 382a. The nozzle 384a is moved to a process location and a standby location by the driver 378. The process location is a location at which the nozzle 384a is arranged at an vertical upper portion of the cup 320, and the standby location is a location that deviates from the vertical upper portion of the cup 320.

The treatment liquid injecting member 383 injects the treatment liquid to the upper surface of the substrate. The treatment liquid may be a conductive liquid. The treatment liquid may be a chemical. The treatment liquid may be a fluoride hydrogen (HF) solution. The treatment liquid may be a standard cleaning (SC-1) solution that includes ammonium hydroxide (NH₄OH), hydrogen peroxide (H₂O₂), and water (H₂O). The treatment liquid injecting unit 383 has a nozzle support 382b, a nozzle 384b, a support 386b, and a driver 388b. The nozzle support 382b, the nozzle 384b, the support 386b, and the driver 388b have configurations that are the same as or similar to the aforementioned configurations of the nozzle support 382a, the nozzle 384a, the support 386a, and the driver 388a of the pure water injecting member 381. One or a plurality of treatment liquid injecting members 383 may be provided.

The gas injecting member 390 injects a drying gas onto the substrate. The drying gas may be a nitrogen gas. The drying gas dries a treatment liquid that is left after the treatment liquid is injected. The gas injecting member 390 may include a fixed injection member 392 and a movable injection member 394. The fixed injection member 392 is fixedly installed in the cup 320. The movable injection member 394 is provided to be rotatable. The movable injection member 394 may be rotated about an axis in a predetermined range such that a drying gas may be injected onto the upper surface of the substrate.

The back nozzle unit 400 supplies a static electricity removing liquid and a drying gas onto a lower surface of the substrate. Hereinafter, the lower surface of the substrate refers to a surface of the substrate opposite to an upper surface, on which a pattern is formed. Referring to FIG. 5, the back nozzle unit 400 includes a support shaft 410, a skirt 420, and a lower nozzle 430. The support shaft 410 is inserted into a hollow portion of the body 342. The support shaft 410 is separated from the body 342, and the support shaft 410 is not rotated when the body 342 is rotated. The skirt 420 is fixedly coupled to an upper end of the support shaft 410. The skirt 420 is provided to protrude from the upper surface of the body 342. The skirt 420 covers the lower nozzle 430 while protecting the lower nozzle 430. The lower nozzle 430 is formed in the support shaft 410 and in the interiors of the skirt 420 to extend from the interior of the support shaft 410 to an upper end of the skirt 420. The lower nozzle 430 injects a static electricity removing liquid and a drying gas. The static electricity removing liquid may be a conductive liquid. The static electricity removing liquid may be a chemical. The static electricity removing liquid may be a fluoride hydrogen (HF) solution. The static electricity removing liquid may be a standard cleaning (SC-1) solution that includes ammonium hydroxide (NH₄OH), hydrogen peroxide (H₂O₂), and water (H₂O). The drying gas may be a nitrogen gas. The drying gas dries a static electricity removing liquid residing on a lower surface of the substrate.

The controller 1000 controls the injection unit 380 and the back nozzle unit 400. In detail, the controller 1000 controls the operation sequence of the injection unit 380 and the back nozzle unit 400. The controller 1000 allows the treatment liquid injecting member 383 to supply the treatment liquid onto the upper surface of the substrate after the pure water injecting member 381 of the injection unit 380 discharges pure water onto the upper surface of the substrate. The controller 1000 allows the back nozzle unit 400 to discharge the static electricity removing liquid onto the lower surface of the substrate before the treatment liquid injecting member 383 supplies the treatment liquid onto the upper surface of the substrate. The controller 1000 allows the back nozzle unit 400 to discharge the static electricity removing liquid after the pure water injecting member 381 discharges pure water. The controller 1000 allows the gas injecting member 390 to inject a drying gas onto the upper surface of the substrate after the treatment liquid is supplied.

Although it has been described that the back nozzle unit 400 supplies a static electricity removing liquid after the pure water injecting member 381 discharges the pure water under the control of the controller 1000, the static electricity removing liquid and the pure water may be discharged at the same time. In detail, the back nozzle unit 400 may discharge a static electricity removing liquid onto the lower surface of the substrate while the pure water injecting member 381 discharges pure water onto the upper surface of the substrate.

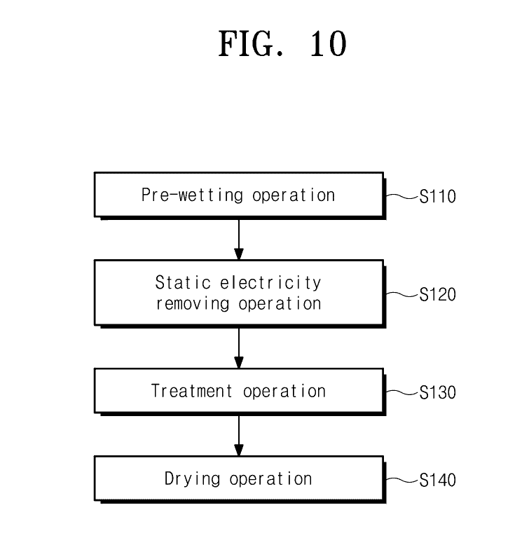

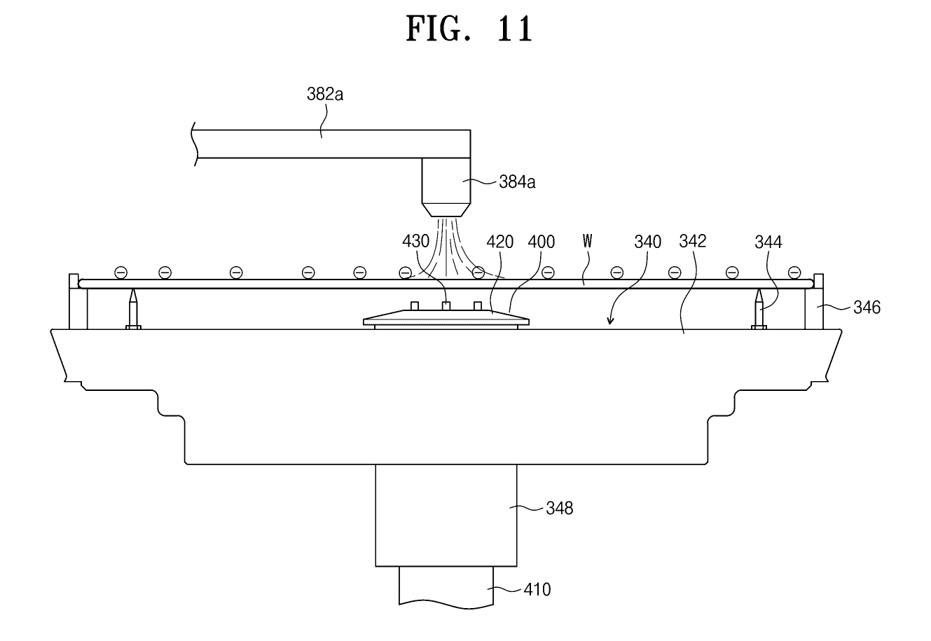

Hereinafter, a method for treating a substrate of a substrate treating apparatus 300 will be described. FIGS. 6 to 9 are views sequentially illustrating a process of treating a substrate. FIG. 10 is a flowchart illustrating a process of treating a substrate. FIGS. 11 to 14 are views sequentially illustrating a process of removing static electricity from the substrate.

A pre-wetting operation of discharging pure water onto an upper surface of the substrate is performed. In the pre-wetting operation S110, pure water is discharged from the pure water injecting member 381 onto the upper surface of the substrate. If pure water makes contact with the substrate, static electricity is generated on the upper surface of the substrate. The static electricity generated then may correspond to negative charges or positive charges. FIGS. 11 to 14 illustrate negative charges for convenience.

After the pre-wetting operation S110, a static electricity removing operation S120 of discharging a static electricity removing liquid onto a lower surface of the substrate may be performed. In the static electricity removing operation S120, static electricity is removed from the substrate. The static electricity removing liquid is discharged from the back nozzle unit 400 onto the lower surface of the substrate. The static electricity removing liquid may be a conductive liquid. The static electricity removing liquid may be a chemical. The static electricity removing liquid may be a fluoride hydrogen (HF) solution. The static electricity removing liquid may be a standard cleaning (SC-1) solution that includes ammonium hydroxide (NH₄OH), hydrogen peroxide (H₂O₂), and water (H₂O). The static electricity on the upper surface of the substrate may be discharged to the outside together with the static electricity removing liquid. Referring to FIGS. 11 to 14, the static electricity on the upper surface of the substrate passes through the interior of the substrate, and is discharged to the lower side of the substrate together with the static electricity removing liquid flowing on the lower surface of the substrate. Accordingly, the static electricity on the surface of the substrate is removed from the substrate.

A treatment operation S130 is performed, after the static electricity removing operation. In the treatment operation S130, the substrate is etched or cleaned. In the treatment operation S130, the treatment liquid is supplied from the treatment liquid injecting member 383 onto the upper surface of the substrate. The treatment liquid may be a conductive liquid. The treatment liquid may be a chemical. The treatment liquid may be a fluoride hydrogen (HF) solution. The treatment liquid may be a standard cleaning (SC-1) solution that includes ammonium hydroxide (NH₄OH), hydrogen peroxide (H₂O₂), and water (H₂O).

After the treatment operation S130, a drying operation S140 may be performed. In the drying operation S140, the left treatment liquid is dried from the substrate. The gas injecting member 390 supplies a drying gas onto the substrate. The drying gas may be a nitrogen gas.

Although it has been exemplified that the static electricity removing operation S120 is performed after the pre-wetting operation S110, the static electricity removing operation S120 and the pre-wetting operation S110 may be performed at the same time. The static electricity removing liquid may be discharged onto the lower surface of the substrate while pure water is discharged onto the upper surface of the substrate.

Although it has been exemplified that the treatment operation S130 and the drying operation S140 are performed, they may be omitted.

According to an embodiment of the inventive concept, static electricity generated on a surface of a substrate may be removed.

Further, according to an embodiment of the inventive concept, an arcing phenomenon generated on a surface of a substrate and damage to a pattern of the substrate may be prevented.

The above-mentioned detailed description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A method for treating a substrate, the method comprising:
a pre-wetting operation of discharging pure water onto an upper surface of the substrate; and
a treatment operation of treating the substrate by supplying a treatment liquid onto the upper substrate, after the pre-wetting operation,
wherein the method further comprises a static electricity removing operation of removing static electricity by discharging a static electricity removing liquid onto a lower surface of the substrate, before the treatment operation.

2. The method of claim 1, wherein the static electricity removing operation is performed after the pre-wetting operation.

3. The method of claim 1, wherein the static electricity removing operation and the pre-wetting operation are performed at the same time.

4. The method of claim 1, wherein the treatment liquid is a conductive liquid.

5. The method of claim 4, wherein the treatment liquid is a fluoride hydrogen (HF) solution or a solution comprising ammonium hydroxide (NH₄OH), hydrogen peroxide (H₂O₂), and water (H₂O).

6. The method of claim 4, wherein the static electricity removing liquid is a chemical.

7. The method of claim 6, wherein the static electricity removing liquid is a conductive liquid.

8. The method of claim 7, wherein the static electricity removing liquid is a fluoride hydrogen (HF) solution or a solution comprising ammonium hydroxide (NH₄OH), hydrogen peroxide (H₂O₂), and water (H₂O).

9. The method of claim 7, wherein the treatment liquid is a chemical.

10. The method of claim 1, further comprising:
a drying operation of drying the substrate, after the treatment operation.

11. The method of claim 1, wherein the static electricity flows through an interior of the substrate from the upper surface of the substrate, and discharged to a lower side of the substrate along the static electricity removing liquid flowing on the lower surface of the substrate to be removed.

12. An apparatus for treating a substrate, the apparatus comprising:
a support unit that supports the substrate;
an injection unit having a pure water injection member that discharges pure water onto an upper surface of the substrate and a treatment liquid injection member that supplies a treatment liquid onto the upper surface of the substrate;
a back nozzle unit that injects a static electricity removing liquid onto a lower surface of the substrate; and
a controller that controls the injection unit and the back nozzle unit,
wherein the controller controls the injection unit and the back nozzle unit such that the treatment liquid injection member supplies a treatment liquid onto the upper surface of the substrate after the pure water injection member discharges the pure water onto the upper surface of the substrate and the back nozzle unit discharges the static electricity removing liquid onto the lower surface of the substrate before the treatment liquid is supplied.

13. The apparatus of claim 12, wherein the controller controls the injection unit and the back nozzle unit such that the static electricity removing liquid and the pure water are discharged at the same time.

14. The apparatus of claim 12, wherein the controller controls the injection unit and the back nozzle unit such that the static electricity removing liquid is discharged after the pure water is discharged.

15. The apparatus of clam 12, wherein the treatment liquid is a conductive liquid.

16. The apparatus of claim 15, wherein the treatment liquid is a fluoride hydrogen (HF) solution or a solution comprising ammonium hydroxide (NH₄OH), hydrogen peroxide (H₂O₂), and water (H₂O).

17. The apparatus of claim 15, wherein the static electricity removing liquid is a chemical.

18. The apparatus of claim 17, wherein the static electricity removing liquid is a conductive liquid.

19. The apparatus of claim 18, wherein the static electricity removing liquid is a fluoride hydrogen (HF) solution or a solution comprising ammonium hydroxide (NH₄OH), hydrogen peroxide (H₂O₂), and water (H₂O).

20. The apparatus of claim 18, wherein the treatment liquid is a chemical.

21. The apparatus of clam 12, wherein the injection unit further comprises:
a gas injecting member that supplies a drying gas onto the upper surface of the substrate, and
wherein the controller controls the injection unit such that the gas injection member injects a gas onto the upper surface of the substrate after the injection unit supplies the treatment liquid onto the substrate.
